(19) United States
(12) Patent Application Publication
(10) Pub. No.: US 2026/0122848 A1
(43) Pub. Date: Apr. 30, 2026

(54) COOLING DISTRIBUTION UNIT AND COOLING CONTROL CABINET WITH IMPROVED MAINTAINABILITY

(71) Applicant: LUXSHARE THERMAL TECHNOLOGIES (HUIZHOU) CO., LTD, Huizhou City (CN)

(72) Inventors: Jun Zhao, Huizhou City (CN); Ga Zhang, Huizhou City (CN); Tao Sun, Huizhou City (CN); Jianhua Chen, Huizhou City (CN); Pengfei Wang, Huizhou City (CN)

(73) Assignee: LUXSHARE THERMAL TECHNOLOGIES (HUIZHOU) CO., LTD, Huizhou City (CN)

(21) Appl. No.: 19/293,481

(22) Filed: Aug. 7, 2025

(30) Foreign Application Priority Data
Oct. 29, 2024 (CN) 202411526730.5

(51) Int. Cl. H05K 7/20

(52) U.S. Cl. CPC H05K 7/20272; H05K 7/20236; H05K 7/20263; H05K 7/20281

(57) ABSTRACT

A cooling distribution unit includes a first pump, a second pump, a pump inlet pipeline, a pump outlet pipeline, a heat exchanger and a first return pipeline. The pump inlet pipeline includes a first inlet end check valve, a first pump inlet pipe, a second inlet end check valve and a second pump inlet pipe. The pump outlet pipeline includes a first outlet end check valve, a first pump outlet pipe, a second outlet end check valve and a second pump outlet pipe. The first pump outlet pipe and/or the second pump outlet pipe are connected to a first heat exchanger inlet. One end of the first return pipeline is connected to a first heat exchanger outlet, and another end is configured to be connected to an immersed liquid cooling cabinet. A cooling control cabinet having the cooling distribution unit is also disclosed.

### CROSS-REFERENCE TO RELATED APPLICATION

This patent application claims priority of a Chinese Patent Application No. 202411526730.5, filed on Oct. 29, 2024 and titled “COOLING DISTRIBUTION UNIT AND COOLING CONTROL CABINET”, the entire content of which is incorporated herein by reference.

### TECHNICAL FIELD

The present disclosure relates to a cooling distribution unit and a cooling control cabinet, which belong to the technical field of immersion liquid cooling.

### BACKGROUND

With the continuous development of high-density business applications such as the Internet of Things, artificial intelligence, virtual reality, and smart cities, the amount of data calculations and computational complexity faced by data centers are increasing rapidly. In order to adapt to the rapidly growing demand for computing power, existing data centers mainly upgrade their computing power by continuously increasing the density of single cabinets, which causes the heat flow density and energy consumption of data centers to continue to rise. In order to deal with the heat dissipation problem of such high heat flux density computing equipment, immersion liquid cooling technology serves as a new, efficient, green and energy-saving data center cooling solution. By immersing the heating device in the cooling liquid, the heating device is in direct contact with the cooling liquid, and the heat generated is transferred to the cooling liquid. Then the mutually isolated primary/secondary side circulation flow paths of the cooling distribution unit (CDU) are used for heat exchange, so that the heat is taken away, thereby creating a circulating, efficient cooling system.

Rack-mounted CDU is generally a cooling distribution unit installed in a standard rack. It is usually sized in rack units to facilitate installation in a data center rack. The rack-mounted CDU is generally suitable for small data centers or scenarios that require liquid cooling deployment in a limited space. The design of the rack-mounted CDU is relatively compact and takes up less space in the computer room.

In the existing technology, due to space limitations, the heat exchange performance of rack-mounted CDU is difficult to effectively improve, and installation and maintenance are inconvenient.

Therefore, it is desirable to improve the cooling distribution unit and cooling control cabinet in related technologies.

### SUMMARY

An object of the present disclosure is to provide an improved cooling distribution unit and an improved cooling control cabinet.

The present disclosure adopts the following technical solution: a cooling distribution unit, configured to dissipate heat from a device in an immersed liquid cooling cabinet, including: a first pump, the first pump being provided with a first inlet and a first outlet; a second pump, the second pump being provided with a second inlet and a second outlet; the first pump and the second pump being arranged in parallel; the first pump and/or the second pump being configured to pump out a first cooling liquid in the immersed liquid cooling cabinet; a pump inlet pipeline, the pump inlet pipeline including a first inlet end check valve connected to the first inlet of the first pump, a first pump inlet pipe connected to the first inlet end check valve, a second inlet end check valve connected to the second inlet of the second pump, and a second pump inlet pipe connected to the second inlet end check valve; a pump outlet pipeline, the pump outlet pipeline including a first outlet end check valve connected to the first outlet of the first pump, a first pump outlet pipe connected to the first outlet end check valve, a second outlet end check valve connected to the second outlet of the second pump, and a second pump outlet pipe connected to the second outlet end check valve; a heat exchanger, the heat exchanger including a first heat exchanger inlet and a first heat exchanger outlet; the first pump outlet pipe and/or the second pump outlet pipe are connected to the first heat exchanger inlet; and a first return pipeline, one end of the first return pipeline being connected to the first heat exchanger outlet, and another end of the first return pipeline being configured to be connected to the immersed liquid cooling cabinet; the first return pipeline including a first main return pipe, a first branch return pipe connected to the first main return pipe, a second branch return pipe connected to the first main return pipe and disposed parallel to the first branch return pipe, and a second main return pipe connected to the first branch return pipe and the second branch return pipe.

The present disclosure also adopts the following technical solution: a cooling control cabinet, including: a cooling distribution unit, the cooling distribution unit being configured to dissipate heat from a device in an immersed liquid cooling cabinet, the cooling distribution unit including: a first pump, the first pump being provided with a first inlet and a first outlet; a second pump, the second pump being provided with a second inlet and a second outlet; the first pump and the second pump being arranged in parallel; the first pump and/or the second pump being configured to pump out a first cooling liquid in the immersed liquid cooling cabinet; a pump inlet pipeline, the pump inlet pipeline including a first inlet end check valve connected to the first inlet of the first pump, a first pump inlet pipe connected to the first inlet end check valve, a second inlet end check valve connected to the second inlet of the second pump, and a second pump inlet pipe connected to the second inlet end check valve; a pump outlet pipeline, the pump outlet pipeline including a first outlet end check valve connected to the first outlet of the first pump, a first pump outlet pipe connected to the first outlet end check valve, a second outlet end check valve connected to the second outlet of the second pump, and a second pump outlet pipe connected to the second outlet end check valve; a heat exchanger, the heat exchanger including a first heat exchanger inlet and a first heat exchanger outlet; the first pump outlet pipe and/or the second pump outlet pipe are connected to the first heat exchanger inlet; and a first return pipeline, one end of the first return pipeline being connected to the first heat exchanger outlet, and another end of the first return pipeline being configured to be connected to the immersed liquid cooling cabinet; the first return pipeline including a first main return pipe, a first branch return pipe connected to the first main return pipe, a second branch return pipe connected to the first main return pipe and disposed parallel to the first branch return pipe, and a second main return pipe connected to the first branch return pipe and the second branch return pipe; a cabinet body, the cabinet body including a bottom wall and a plurality of side walls; the first pump and the second pump being installed on the bottom wall; and at least one running wheel, the running wheel being installed at a bottom of the bottom wall.

### BRIEF DESCRIPTION OF DRAWINGS

FIG. 1 is a working principle diagram of a cooling distribution unit of the present disclosure;

FIG. 2 is a perspective schematic view of a cooling control cabinet in accordance with an embodiment of the present disclosure;

FIG. 3 is a partially exploded perspective view of FIG. 2, in which one side wall is separated;

FIG. 4 is a partially exploded perspective view of FIG. 3 from another angle;

FIG. 5 is a front view of FIG. 3 with the one side wall removed;

FIG. 6 is a schematic perspective view of the cooling control cabinet of the present disclosure with some side walls and a top wall removed;

FIG. 7 is a front view of FIG. 6;

FIG. 8 is a perspective schematic view of the cooling distribution unit in accordance with an embodiment of the present disclosure;

FIG. 9 is a front view of FIG. 8;

FIG. 10 is a rear view of FIG. 8;

FIG. 11 is a left view of FIG. 8;

FIG. 12 is a right view of FIG. 8;

FIG. 13 is a top view of FIG. 8; and

FIG. 14 is a bottom view of FIG. 8.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

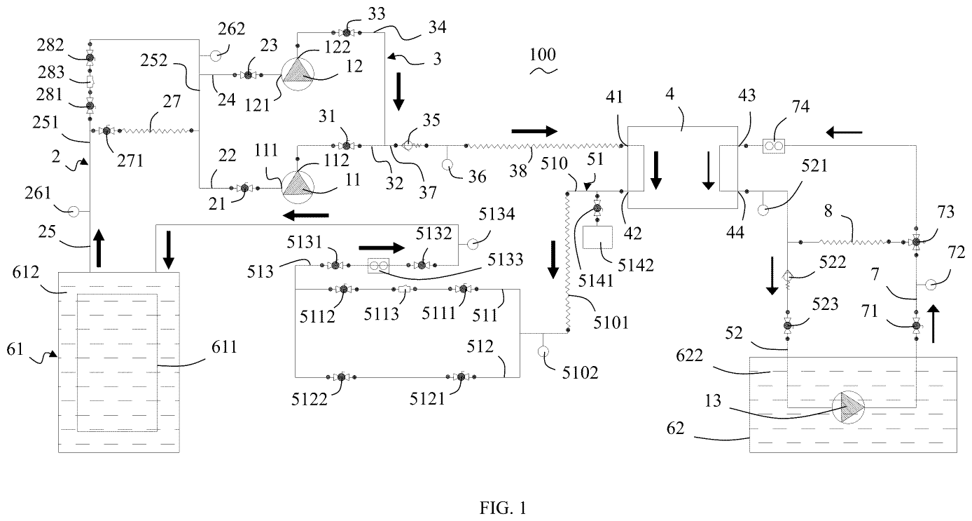

Referring to FIG. 1, the present disclosure discloses a cooling distribution unit 100, which includes a primary side circulation flow path and a secondary side circulation flow path. The secondary side circulation flow path includes a first pump 11, a second pump 12, a pump inlet pipeline 2, a pump outlet pipeline 3, a heat exchanger 4, a first return pipeline 51 and an immersed liquid cooling cabinet 61. The primary side circulation flow path includes a third pump 13, an outlet pipeline 7 connected to an outlet of the third pump 13, the heat exchanger 4 connected to the outlet pipeline 7, a second return pipeline 52 connected to an inlet of the second pump 13, and a chiller 62. The immersed liquid cooling cabinet 61 is installed with a heating device 611 that needs to dissipate heat and a first cooling liquid 612 for soaking the heating device 611. The heating device 611 includes but is not limited to a server. The first cooling liquid 612 includes but is not limited to water. The chiller 62 includes a second cooling liquid 622, and the second cooling liquid 622 includes but is not limited to water. The first cooling liquid 612 of the primary side circulation flow path and the second cooling liquid 622 of the secondary side circulation flow path perform heat exchange in the heat exchanger 4 in order to achieve temperature control.

The first pump 11 is provided with a first inlet 111 and a first outlet 112.

The second pump 12 is provided with a second inlet 121 and a second outlet 122. The first pump 11 and the second pump 12 are arranged in parallel to facilitate maintenance and replacement of one of the pumps without affecting the operation of the entire system. It is understandable to those skilled in the art that the types of the first pump 11 and the second pump 12 can be flexibly selected from existing technologies as needed, which will not be described in detail in the present disclosure.

The pump inlet pipeline 2 includes a first inlet end check valve 21 connected to the first inlet 111 of the first pump 11, a first pump inlet pipe 22 connected to the first inlet end check valve 21, a second inlet end check valve 23 connected to the second inlet 121 of the second pump 12, a second pump inlet pipe 24 connected to the second inlet end check valve 23, and at least one inlet pipeline sensor configured to detect the pump inlet pipeline 2. As shown in FIG. 1, the first inlet end check valve 21 is detachably connected in the pump inlet pipeline 2. The two small black dots located on two sides of the first inlet end check valve 21 indicate that these positions are detachably connected. To simplify the description, the two small black dots located on two sides of any component shown in FIG. 1 indicate that these positions are detachably connected.

Specifically, in the illustrated embodiment of the present disclosure, the pump inlet pipeline 2 further includes a main inlet pipe 25 connecting the first pump inlet pipe 22 and the second pump inlet pipe 24. The main inlet pipe 25 is configured to be in fluid communication with the first cooling liquid 612 in the immersed liquid cooling cabinet 61, so that the high-temperature first cooling liquid 612 is able to flow from the main inlet pipe 25 into the secondary side circulation flow path of the cooling distribution unit 100 through the first pump 11 and/or the second pump 12.

In the illustrated embodiment of the present disclosure, the main inlet pipe 25 includes a first main inlet pipe 251 and a second main inlet pipe 252 connected to the first main inlet pipe 251. The inlet pipeline sensor includes a first main inlet pipeline sensor 261 provided on the first main inlet pipe 251 and a second main inlet pipeline sensor 262 provided on the second main inlet pipe 252. In an embodiment of the present disclosure, the first main inlet pipeline sensor 261 and the second main inlet pipeline sensor 262 are both temperature-pressure integrated sensors. The redundant design of the temperature-pressure integrated sensor is able to ensure the reliability of detection and signal feedback under single fault conditions. Of course, it is understandable to those skilled in the art that the temperature-pressure integrated sensor can also be replaced by a combination of a temperature sensor and a pressure sensor.

Besides, the main inlet pipe 25 further includes a first bypass pipe 27 connecting the first main inlet pipe 251 and the second main inlet pipe 252, and a first regulating valve 271 connected to the first bypass pipe 27. The first regulating valve 271 may be a manual butterfly valve. In one embodiment of the present disclosure, the first bypass pipe 27 is a first metal corrugated pipe (for example, a stainless steel corrugated pipe), which reduces processing accuracy and difficulty, and improves installation flexibility.

The first main inlet pipe 251 is further connected with a first manual butterfly valve 281, a second manual butterfly valve 282, and a first filter 283 (for example, a Y-type filter) connected between the first manual butterfly valve 281 and the second manual butterfly valve 282. It is understandable to those skilled in the art that by arranging the first manual butterfly valve 281 and the second manual butterfly valve 282, the first filter 283 can be maintained or replaced without affecting the operation of the system. When the first filter 283 is being maintained or replaced, the first manual butterfly valve 281 and the second manual butterfly valve 282 are in a closed position (an off position, the same hereinafter). At this time, the first regulating valve 271 is in an open position (an on position, the same hereinafter). The cooling liquid may flow to the first inlet 111 of the first pump 11 and/or the second inlet 121 of the second pump 12 through the first bypass pipe 27. Normally, the first regulating valve 271 is in a closed position, and the first manual butterfly valve 281 and the second manual butterfly valve 282 are in an open position, so that the cooling liquid is able to flow from the first manual butterfly valve 281, the first filter 283 and the second manual butterfly valve 282 to the first inlet 111 of the first pump 11 and/or the second inlet 121 of the second pump 12. The second inlet main pipeline sensor 262 connected downstream of the first filter 283 along a flow direction of the cooling liquid is able to detect the system pressure. When the system pressure exceeds a set value, a signal will be sent to remind the first filter 283 that it may be blocked and needs to be maintained or replaced.

The pump outlet pipeline 3 includes a first outlet end check valve 31 connected to the first outlet 112 of the first pump 11, a first pump outlet pipe 32 connected to the first outlet end check valve 31, a second outlet end check valve 33 connected to the second outlet 122 of the second pump 12, a second pump outlet pipe 34 connected to the second outlet end check valve 33, a first one-way valve 35 connected downstream of the first outlet 112 of the first pump 11 and the second outlet 122 of the second pump 12, and at least one first outlet pipeline sensor 36 configured to detect the pump outlet pipeline 3. In an embodiment of the present disclosure, the first outlet pipeline sensor 36 is a temperature-pressure integrated sensor.

It is understandable to those skilled in the art that by closing the first inlet end check valve 21 and the first outlet end check valve 31, it is possible to maintain or replace the first pump 11 connected between the first inlet end check valve 21 and the first outlet end check valve 31. Similarly, by closing the second inlet end check valve 23 and the second outlet end check valve 33, it is possible to maintain or replace the second pump 12 connected between the second inlet end check valve 23 and the second outlet end check valve 33.

The heat exchanger 4 includes a first heat exchanger inlet 41, a first heat exchanger outlet 42, a second heat exchanger inlet 43 and a second heat exchanger outlet 44. The first heat exchanger inlet 41 and the first heat exchanger outlet 42 are located on a same side of the heat exchanger 4, and communicate with each other. The second heat exchanger inlet 43 and the second heat exchanger outlet 44 are located on another same side of the heat exchanger 4, and communicate with each other. The first pump outlet pipe 32 and/or the second pump outlet pipe 34 are connected to the first heat exchanger inlet 41.

In an embodiment of the present disclosure, the heat exchanger 4 is a double flow channel plate heat exchanger. The first heat exchanger inlet 41 and the first heat exchanger outlet 42 are in communication with one flow channel of the double flow channel plate heat exchanger; and the second heat exchanger inlet 43 and the second heat exchanger outlet 44 are in communication with another flow channel of the double flow channel plate heat exchanger.

Specifically, in the illustrated embodiment of the disclosure, the pump outlet pipeline 3 includes a main outlet pipe 37 connecting the first pump outlet pipe 32 and the second pump outlet pipe 34. The first one-way valve 35 and the first outlet pipeline sensor 36 are both connected to the main outlet pipe 37. The first one-way valve 35 is used to prevent the first cooling liquid 612 from being sucked back into the first pump 11 and/or the second pump 12. The pump outlet pipeline 3 further includes a second metal corrugated pipe 38 connected between the main outlet pipe 37 and the first heat exchanger inlet 41. The arrangement of the second metal corrugated pipe 38 is beneficial to improving the flexibility of pipeline installation.

One end of the first return pipeline 51 is connected to the first heat exchanger outlet 42, and the other end of the first return pipeline 51 is configured to be connected to the immersed liquid cooling cabinet 61 to return the cooled first cooling liquid 612 back to the immersed liquid cooling cabinet 61.

In the illustrated embodiment of the present disclosure, the first return pipeline 51 includes a first main return pipe 510, a first branch return pipe 511 connected to the first main return pipe 510, a second branch return pipe 512 connected to the first main return pipe 510 and disposed parallel to the first branch return pipe 511, a second main return pipe 513 connected to the first branch return pipe 511 and the second branch return pipe 512, and a return pipeline sensor.

The first return pipeline 51 further includes a second regulating valve 5141 connected to the first main return pipe 510 and disposed adjacent to the first heat exchanger outlet 42, and a pressure regulating device 5142 connected to the second regulating valve 5141. The second regulating valve 5141 may be a manual butterfly valve. The pressure regulating device 5142 includes, but is not limited to, an expansion tank. The pressure regulating device 5142 is used to compensate for the volume change of the first cooling liquid 612 when the temperature changes in order to prevent the system pressure from being too high.

The first main return pipe 510 further includes a third metal corrugated pipe 5101 and a first return pipeline sensor 5102 connected downstream of the third metal corrugated pipe 5101. The first return pipeline sensor 5102 is a temperature-pressure integrated sensor. The return pipeline sensor includes the first return pipeline sensor 5102.

The first branch return pipe 511 is provided with a first control valve 5111, a second control valve 5112, and a second filter 5113 (for example, a Y-type filter) connected between the first control valve 5111 and the second control valve 5112. It is understandable to those skilled in the art that by providing the first control valve 5111 and the second control valve 5112, the second filter 5113 can be maintained or replaced without affecting the operation of the system. In an embodiment of the present disclosure, both the first control valve 5111 and the second control valve 5112 are manual butterfly valves.

The second branch return pipe 512 is provided with a third control valve 5121 and a fourth control valve 5122. In an embodiment of the present disclosure, both the third control valve 5121 and the fourth control valve 5122 are manual butterfly valves.

The second main return pipe 513 is provided with a fifth control valve 5131, a sixth control valve 5132, a first flow device 5133 connected between the fifth control valve 5131 and the sixth control valve 5132, and a second return pipeline sensor 5134. The first flow device 5133 is a flow meter or a flow sensor. The second return pipeline sensor 5134 is a temperature-pressure integrated sensor. The return pipeline sensor includes the second return pipeline sensor 5134.

The outlet pipeline 7 includes a first control valve 71, a second outlet pipeline sensor 72 connected downstream of the first control valve 71, a three-way electric valve 73 connected downstream of the second outlet pipeline sensor 72, and a second flow device 74 connected between the three-way electric valve 73 and the second heat exchanger inlet 43. In an embodiment of the present disclosure, the first control valve 71 may be a manual butterfly valve. The second outlet pipeline sensor 72 is a temperature-pressure integrated sensor. The second flow device 74 is a flow meter or a flow sensor.

The second return pipeline 52 includes a third return pipeline sensor 521, a second one-way valve 522 connected downstream of the third return pipeline sensor 521, and a second control valve 523 connected downstream of the second one-way valve 522. In one embodiment of the present disclosure, the third return pipeline sensor 521 is a temperature-pressure integrated sensor. The second control valve 523 may be a manual butterfly valve.

The primary side circulation flow path further includes a second bypass pipe 8 connected between the three-way electric valve 73 and the second return pipeline 52. The three-way electric valve 73 is able to control whether the second bypass pipe 8 is on or off. In one embodiment of the present disclosure, the second bypass pipe 8 is a fourth metal corrugated pipe (for example, a stainless steel corrugated pipe) to reduce processing accuracy and difficulty, and improve installation flexibility.

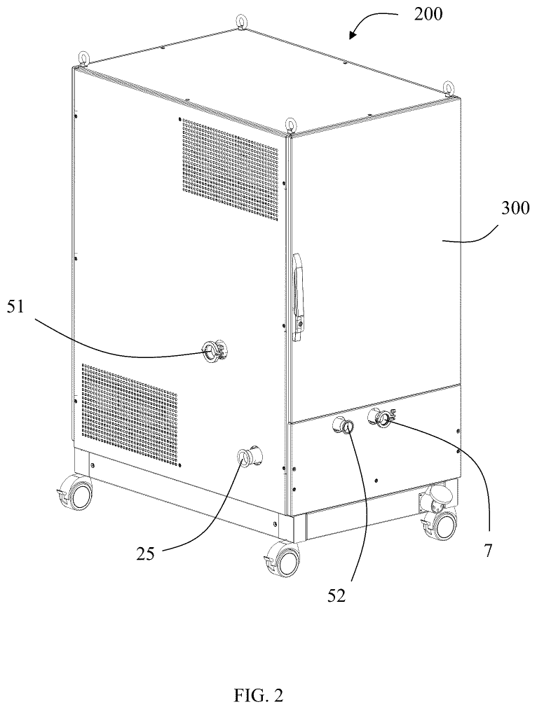

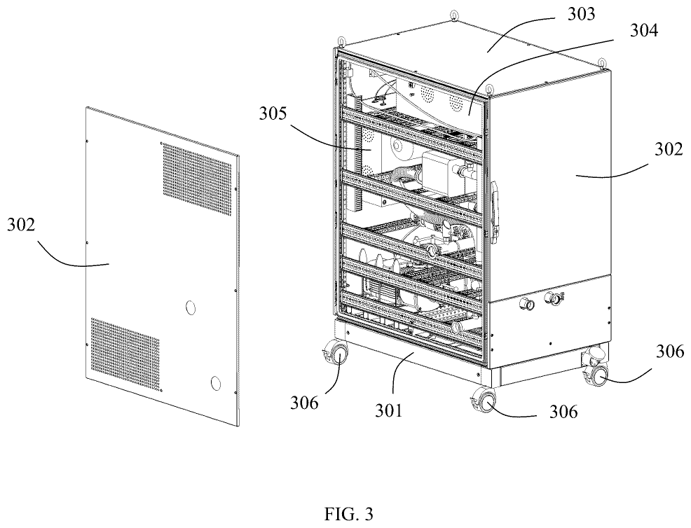

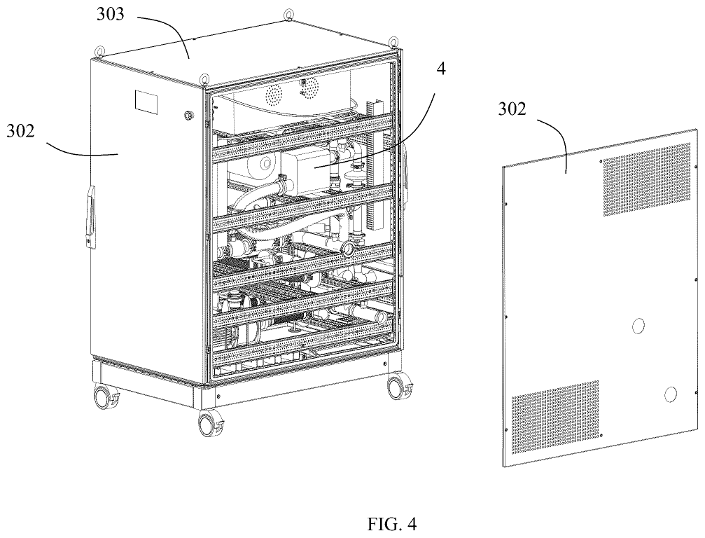

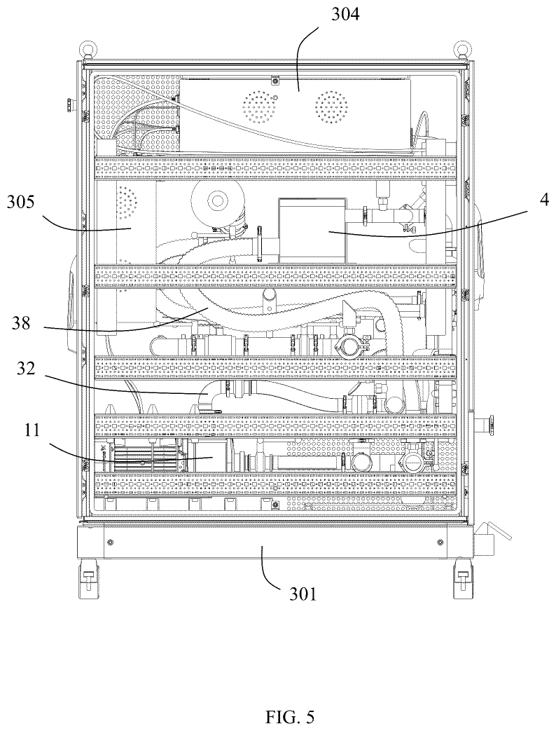

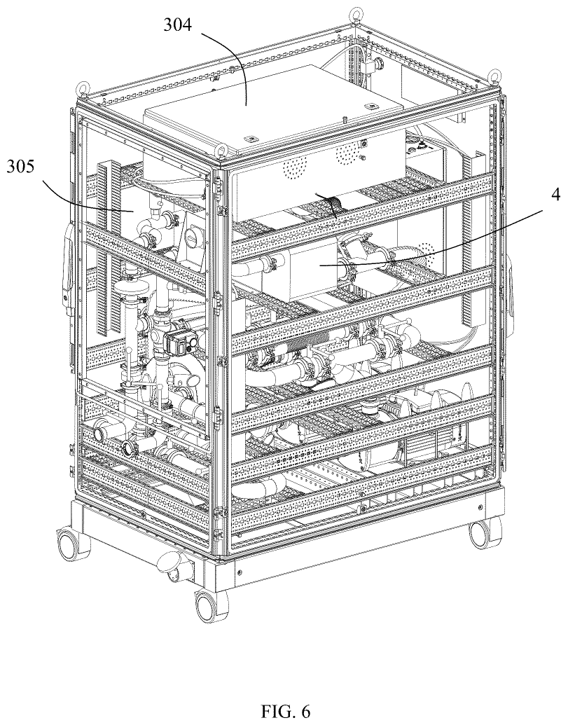

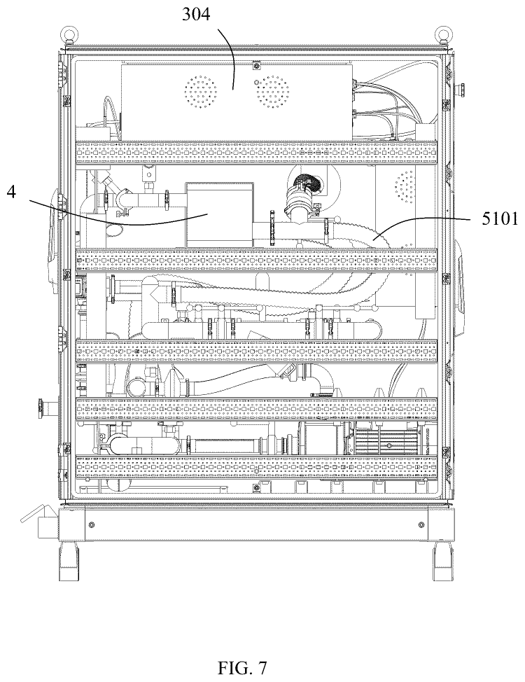

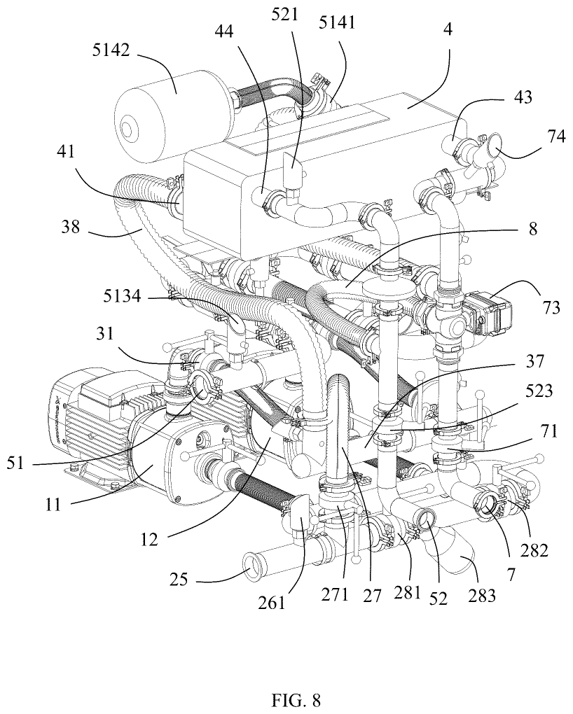

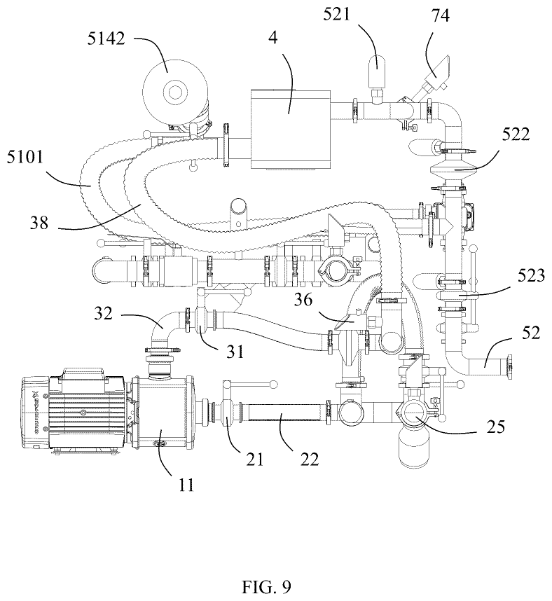

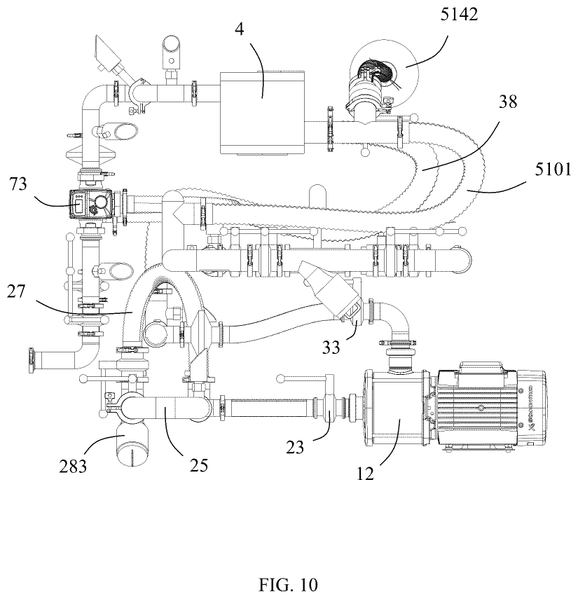

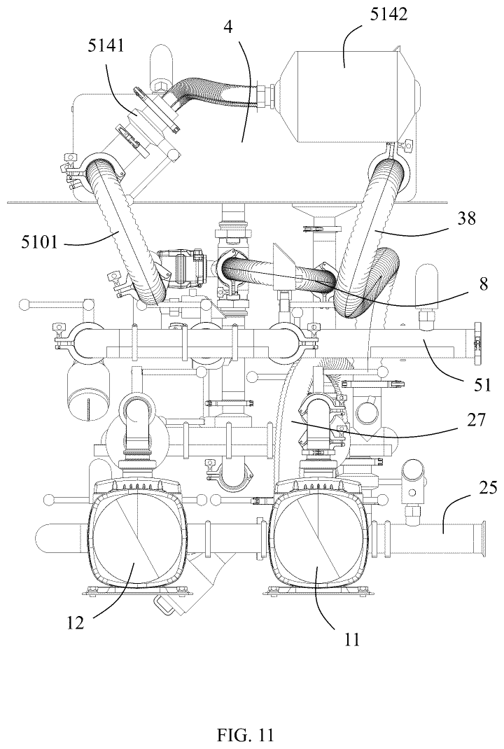

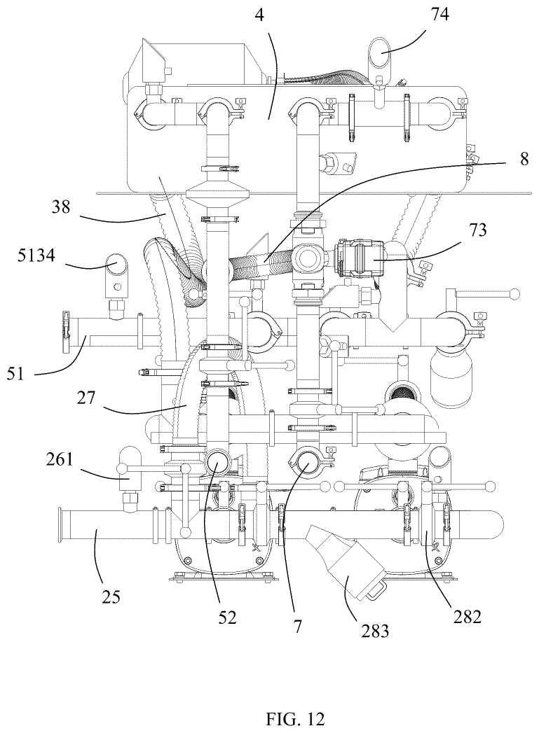

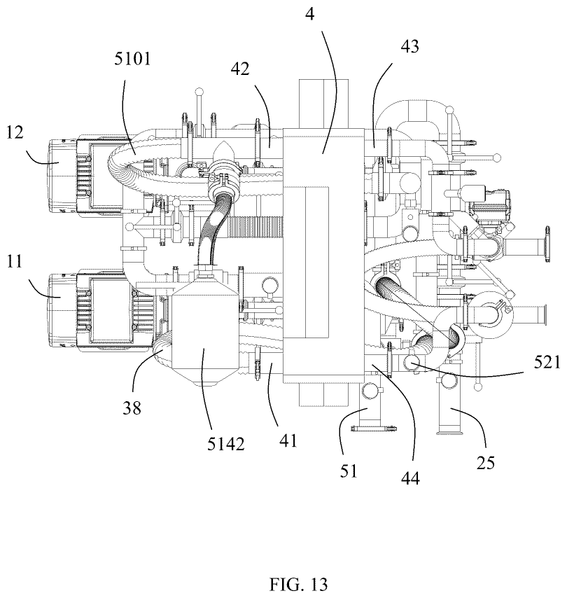

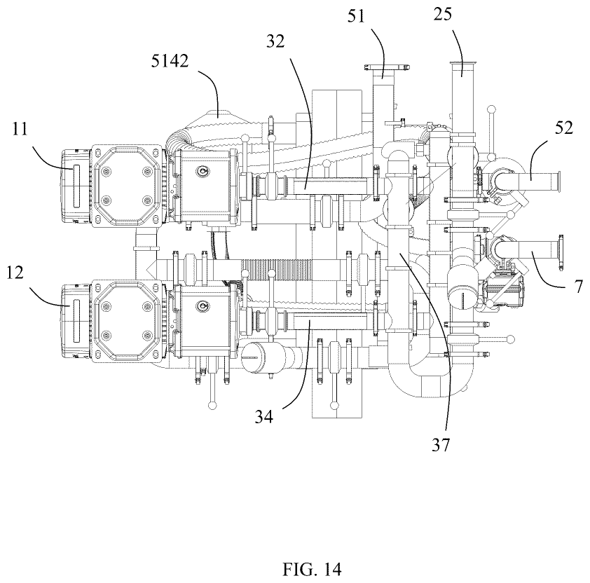

Referring to FIG. 2 to FIG. 14, the present disclosure also discloses a cooling control cabinet 200, which includes the cooling distribution unit 100 and a cabinet body 300. The specific structures of the cooling distribution unit 100 disclosed in FIG. 2 to FIG. 14 is based on the principle of the cooling distribution unit 100 shown in FIG. 1. Of course, it is understandable to those skilled in the art that the specific structures of the cooling distribution unit 100 disclosed in FIG. 2 to FIG. 14 do not necessarily require that the installation positions of the components are exactly the same as shown in the principle of the cooling distribution unit 100 in FIG. 1. The cabinet body 300 includes a bottom wall 301, a plurality of side walls 302 and a top wall 303. The first pump 11 and the second pump 12 are installed on the bottom wall 301 to facilitate installation and maintenance. The cabinet body 300 is further provided with a high-power distribution box 304 and a weak-power distribution box 305. The high-power distribution box 304 and the weak-power distribution box 305 are located in the middle and upper location of the cabinet body 300. The strong power distribution box 304 is located below the top wall 303. The weak-power distribution box 305 is located on an inner side of one of the side walls 302. The high-power distribution box 304 and the weak-power distribution box 305 disclosed in the present disclosure are both set up independently and separated from the fluid pipeline system, thereby helping to avoid interference failures. Of course, it is understandable to those skilled in the art that the cooling control cabinet 200 may further includes other components such as switches.

In addition, in the illustrated embodiment of the present disclosure, the cooling control cabinet 200 further includes at least one traveling wheel 306 installed at a bottom of the bottom wall 301 to facilitate moving the cooling control cabinet 200.

Compared with the prior art, the cooling distribution unit 100 and the cooling control cabinet 200 of the present disclosure include the first pump 11 and the second pump 12 arranged in parallel. Combined with the first inlet end check valve 21, the second inlet end check valve 23, the first outlet end check valve 31 and the second outlet end check valve 33 that cooperate with the first pump 11 and the second pump 12, the present disclosure enables maintenance or replacement of the first pump 11 or the second pump 12 that may malfunction without affecting the operation of the system. In addition, by providing the first inlet main pipeline sensor 261, the second inlet main pipeline sensor 262, the first outlet pipeline sensor 36, the second outlet pipeline sensor 72, the first return pipeline sensor 5102 and the second return pipeline 521, the present disclosure is able to monitor the cooling capacity, flow rate, pressure and temperature of relevant pipelines, thereby facilitating the maintenance of pipelines that may malfunction.

Besides, in order to cope with the comprehensive cooling of the equipment in the entire immersed cabinet, the cooling distribution unit 100 and the cooling control cabinet 200 of the present disclosure is able to provide independent cooling for each cabinet more directly, thereby achieving a more uniform and comprehensive cooling effect.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A cooling distribution unit, configured to dissipate heat from a device in an immersed liquid cooling cabinet, comprising:
a first pump, the first pump being provided with a first inlet and a first outlet;
a second pump, the second pump being provided with a second inlet and a second outlet; the first pump and the second pump being arranged in parallel; the first pump and/or the second pump being configured to pump out a first cooling liquid in the immersed liquid cooling cabinet;
a pump inlet pipeline, the pump inlet pipeline comprising a first inlet end check valve connected to the first inlet of the first pump, a first pump inlet pipe connected to the first inlet end check valve, a second inlet end check valve connected to the second inlet of the second pump, and a second pump inlet pipe connected to the second inlet end check valve;
a pump outlet pipeline, the pump outlet pipeline comprising a first outlet end check valve connected to the first outlet of the first pump, a first pump outlet pipe connected to the first outlet end check valve, a second outlet end check valve connected to the second outlet of the second pump, and a second pump outlet pipe connected to the second outlet end check valve;
a heat exchanger, the heat exchanger comprising a first heat exchanger inlet and a first heat exchanger outlet; the first pump outlet pipe and/or the second pump outlet pipe are connected to the first heat exchanger inlet; and
a first return pipeline, one end of the first return pipeline being connected to the first heat exchanger outlet, and another end of the first return pipeline being configured to be connected to the immersed liquid cooling cabinet; the first return pipeline comprising a first main return pipe, a first branch return pipe connected to the first main return pipe, a second branch return pipe connected to the first main return pipe and disposed parallel to the first branch return pipe, and a second main return pipe connected to the first branch return pipe and the second branch return pipe.

2. The cooling distribution unit according to claim 1, wherein the pump inlet pipeline further comprises at least one inlet pipeline sensor for detecting the pump inlet pipeline; and the pump outlet pipeline further comprises at least one first outlet pipeline sensor for detecting the pump outlet pipeline.

3. The cooling distribution unit according to claim 1, wherein the first return pipeline comprises at least one return pipeline sensor; and the first branch return pipe and the second branch return pipe are respectively provided with at least one control valve.

4. The cooling distribution unit according to claim 2, wherein the pump inlet pipeline further comprises a main inlet pipe connecting the first pump inlet pipe and the second pump inlet pipe; the main inlet pipe is configured to be in communication with the first cooling liquid in the immersion liquid cooling cabinet.

5. The cooling distribution unit according to claim 4, wherein the main inlet pipe comprises a first main inlet pipe and a second main inlet pipe connected to the first main inlet pipe;
the inlet pipeline sensor comprises a first main inlet pipeline sensor provided on the first main inlet pipe and a second main inlet pipeline sensor provided on the second main inlet pipe.

6. The cooling distribution unit according to claim 5, wherein the main inlet pipe further comprises a first bypass pipe connecting the first main inlet pipe and the second main inlet pipe, and a first regulating valve connected to the first bypass pipe.

7. The cooling distribution unit according to claim 5, wherein the first main inlet pipe is further connected with a first manual butterfly valve, a second manual butterfly valve, and a first filter connected between the first manual butterfly valve and the second manual butterfly valve.

8. The cooling distribution unit according to claim 2, wherein the pump outlet pipeline comprises a main outlet pipe connecting the first pump outlet pipe and the second pump outlet pipe; the first outlet pipeline sensor is connected to the main outlet pipe.

9. The cooling distribution unit according to claim 8, wherein the pump outlet pipeline further comprises a second metal corrugated pipe connected between the main outlet pipe and the first heat exchanger inlet.

10. The cooling distribution unit according to claim 1, wherein the first return pipeline further comprises a second regulating valve connected to the first main return pipe and disposed adjacent to the first heat exchanger outlet, and a pressure regulating device connected to the second regulating valve.

11. The cooling distribution unit according to claim 3, wherein the first main return pipe further comprises a third metal corrugated pipe and a first return pipeline sensor connected downstream of the third metal corrugated pipe; the at least one return pipeline sensor comprises the first return pipeline sensor.

12. The cooling distribution unit according to claim 3, wherein the first branch return pipe is provided with a first control valve, a second control valve and a second filter connected between the first control valve and the second control valve; the at least one control valve of the first branch return pipe comprises the first control valve and the second control valve.

13. The cooling distribution unit according to claim 3, wherein the second branch return pipe is provided with a third control valve and a fourth control valve; the at least one control valve of the second branch return pipe comprises the third control valve and the fourth control valve.

14. The cooling distribution unit according to claim 3, wherein the second main return pipe is provided with a fifth control valve, a sixth control valve, a first flow device connected between the fifth control valve and the sixth control valve, and a second return pipeline sensor;
the at least one return pipeline sensor comprises the second return pipeline sensor.

15. The cooling distribution unit according to claim 1, further comprising a primary side circulation flow path and a secondary side circulation flow path;
the heat exchanger comprises a second heat exchanger inlet and a second heat exchanger outlet;
the primary side circulation flow path comprises an outlet pipeline connected to the second heat exchanger inlet and a second return pipeline connected to the second heat exchanger outlet;
the secondary side circulation flow path comprises the first pump and/or the second pump, the pump inlet pipeline, the pump outlet pipeline and the first return pipeline.

16. The cooling distribution unit according to claim 15, wherein the outlet pipeline comprises a first control valve, a second outlet pipeline sensor connected downstream of the first control valve, a three-way electric valve connected downstream of the second outlet pipeline sensor, and a second flow device connected between the three-way electric valve and the second heat exchanger inlet.

17. The cooling distribution unit according to claim 15, wherein the second return pipeline comprises a third return pipeline sensor, a second one-way valve connected downstream of the third return pipeline sensor, and a second control valve connected downstream of the second one-way valve.

18. The cooling distribution unit according to claim 16, wherein the primary side circulation flow path further comprises a second bypass pipe connected between the three-way electric valve and the second return pipeline; the three-way electric valve is configured to control whether the second bypass pipe is on or off.

19. A cooling control cabinet, comprising:
a cooling distribution unit, the cooling distribution unit being configured to dissipate heat from a device in an immersed liquid cooling cabinet, the cooling distribution unit comprising:
a first pump, the first pump being provided with a first inlet and a first outlet;
a second pump, the second pump being provided with a second inlet and a second outlet; the first pump and the second pump being arranged in parallel; the first pump and/or the second pump being configured to pump out a first cooling liquid in the immersed liquid cooling cabinet;
a pump inlet pipeline, the pump inlet pipeline comprising a first inlet end check valve connected to the first inlet of the first pump, a first pump inlet pipe connected to the first inlet end check valve, a second inlet end check valve connected to the second inlet of the second pump, and a second pump inlet pipe connected to the second inlet end check valve;
a pump outlet pipeline, the pump outlet pipeline comprising a first outlet end check valve connected to the first outlet of the first pump, a first pump outlet pipe connected to the first outlet end check valve, a second outlet end check valve connected to the second outlet of the second pump, and a second pump outlet pipe connected to the second outlet end check valve;
a heat exchanger, the heat exchanger comprising a first heat exchanger inlet and a first heat exchanger outlet; the first pump outlet pipe and/or the second pump outlet pipe are connected to the first heat exchanger inlet; and
a first return pipeline, one end of the first return pipeline being connected to the first heat exchanger outlet, and another end of the first return pipeline being configured to be connected to the immersed liquid cooling cabinet; the first return pipeline comprising a first main return pipe, a first branch return pipe connected to the first main return pipe, a second branch return pipe connected to the first main return pipe and disposed parallel to the first branch return pipe, and a second main return pipe connected to the first branch return pipe and the second branch return pipe;
a cabinet body, the cabinet body comprising a bottom wall and a plurality of side walls; the first pump and the second pump being installed on the bottom wall; and
at least one running wheel, the running wheel being installed at a bottom of the bottom wall.

20. The cooling control cabinet according to claim 19, wherein the pump inlet pipeline further comprises at least one inlet pipeline sensor for detecting the pump inlet pipeline; and the pump outlet pipeline further comprises at least one first outlet pipeline sensor for detecting the pump outlet pipeline; and
wherein the first return pipeline comprises at least one return pipeline sensor; and the first branch return pipe and the second branch return pipe are respectively provided with at least one control valve.
